(19) United States
(12) Patent Application Publication
(10) Pub. No.: US 2022/0139740 A1
(43) Pub. Date: May 5, 2022

(54) CHAMBER INTERFACE FOR LINKED PROCESSING TOOLS

(71) Applicant: Applied Materials, Inc., Santa Clara, CA (US)

(72) Inventors: Robert I. Decottignies, San Carlos, CA (US); Marek Radko, San Jose, CA (US)

(21) Appl. No.: 17/174,732

(22) Filed: Feb. 12, 2021

Related U.S. Application Data
(63) Continuation-in-part of application No. 17/171,304, filed on Feb. 9, 2021, now abandoned.
(60) Provisional application No. 63/108,864, filed on Nov. 2, 2020.
(60) Provisional application No. 63/108,864, filed on Nov. 2, 2020.

(51) Int. Cl. H01L 21/67; H01L 21/687; B65G 47/90

(52) U.S. Cl. CPC H01L 21/67196; B65G 47/90; H01L 21/67184; H01L 21/68707

(57) ABSTRACT

Embodiments described herein provide for link tools and linked processing systems having two or more processing tools connected by one or more link tools. Each arrangement of the link processing system includes adjacent processing tools coupled to a link chamber at the transfer modules at the backend of the processing tools. The backend coupling utilizes of floor space away from the factory interfaces of the processing tools. The link chambers have at least five facets. The system further includes two or more transfer vias. Each transfer via is coupled to a facet of the link chamber. The transfer vias are connectable to transfer modules of processing tools. The system further includes a link robot disposed in the link chamber operable to transfer one or more substrates between the transfer vias connectable to the transfer modules of the processing tools.

### CROSS-REFERENCE TO RELATED APPLICATIONS

This application is a continuation-in-part of U.S. patent application Ser. No. 17/171,304, dated Feb. 9, 2021, which claims the benefit of U.S. Provisional Patent Application No. 63/108,864, dated Nov. 2, 2020. This application also claims the benefit of U.S. Provisional Patent Application No. 63/108,864, dated Nov. 2, 2020. Each of these patent applications are incorporated by reference in their entirety.

### BACKGROUND

### Field

Embodiments of the present disclosure relate to link tools and linked processing systems having two or more processing tools connected by one or more link tools.

### Description of the Related Art

Manufacturing of semiconductor devices typically involves performing a sequence of procedures with respect to a substrate or “wafer” such as a silicon substrate, a glass plate, etc. These steps may include polishing, deposition, etching, photolithography, heat treatment, and so forth. Usually a number of different processing steps may be performed in a single processing system or “tool” which includes a plurality of processing chambers. However, it is generally the case that other processes are performed at other processing locations within a fabrication facility, and it is accordingly necessary that substrates be transported within the fabrication facility from one processing location to another. Depending on the type of semiconductor device to be manufactured, there may be a relatively large number of processing steps employed, to be performed at many different processing locations within the fabrication facility.

It is conventional to transport substrates from one processing location to another within substrate carriers such as sealed pods, cassettes, containers and so forth. It is also conventional to employ automated substrate carrier transport devices, such as automatic guided vehicles, overhead transport systems, substrate carrier handling robots, etc., to move substrate carriers from location to location within the fabrication facility or to transfer substrate carriers from or to a substrate carrier transport device.

Such transport of substrates typically involves exposing the substrates to room air, or at least to non-vacuum conditions. Either may expose the substrates to an undesirable environment (e.g., oxidizing species) and/or contaminants. Accordingly what is needed in the art are ways to prevent exposing substrates to undesirable environments when transferring substrates between processing systems.

### SUMMARY

In one embodiment, a system is provided. The system includes a link chamber having at least five facets. The system further includes two or more transfer vias. Each transfer via is coupled to a facet of the link chamber. The transfer vias are connectable to transfer modules of processing tools. The system further includes a link robot disposed in the link chamber operable to transfer one or more substrates between the transfer vias connectable to the transfer modules of the processing tools.

In another embodiment, a system is provided. The system includes a link tool. The link tool includes a link chamber having at least five facets and a first transfer via coupled to a first facet of the link chamber and a second transfer via coupled to a second facet of the link chamber. The link tool further includes a link robot disposed in the link chamber. The system further includes a first processing tool coupled to the first transfer via and a second processing tool coupled to the second transfer via. Each of the first processing tool and the second processing tool include a first transfer module. The first transfer module includes load lock chambers coupled between a factory interface and a first transfer chamber of the first transfer module. The first transfer module further includes an ancillary chamber and first, second, and third process chambers coupled to the first transfer chamber. The first processing tool further includes a second transfer module. The second transfer module includes pass-through chambers connecting the first transfer module and the second transfer module. The second transfer module further includes fourth, fifth, sixth, and seventh process chambers coupled to a second transfer chamber. The second transfer chamber is coupled to one of the first transfer via or the second transfer via.

In yet another embodiment, a system is provided. The system includes a first link tool. the first link tool includes a link chamber having at least five facets and a first transfer via coupled to a first facet of the link chamber, a second transfer via coupled to a second facet of the link chamber, and a third transfer via coupled to a third facet of the link chamber. The first link tool further includes a link robot disposed in the link chamber. The system further includes a first processing tool coupled to the first transfer via, a second processing tool coupled to the second transfer via, and a third processing tool coupled to the third transfer via. Each of the first processing tool, the second processing tool, and the third processing tool include a first transfer module. The first transfer module includes load lock chambers coupled between a factory interface and a first transfer chamber of the first transfer module. The first transfer module further includes an ancillary chamber and first, second, and third process chambers coupled to the first transfer chamber. Each of the first processing tool, the second processing tool, and the third processing tool include a second transfer module. The second transfer module includes pass-through chambers connecting the first transfer module and the second transfer module. The second transfer module further includes at least fourth, fifth, and sixth process chambers coupled to a second transfer chamber, the second transfer chamber coupled one of the first transfer via, the second transfer via, or the third transfer via.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, top view of a link tool according to embodiments described herein.

FIGS. 2A-2H are schematic, top views of arrangements of a linked processing system according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to link tools and linked processing systems having two or more processing tools connected by one or more link tools. Each arrangement of the link processing system includes adjacent processing tools coupled to a link chamber at the transfer modules at the backend of the processing tools. The backend coupling utilizes of floor space away from the factory interfaces of the processing tools, and allows the transfer of the substrates in a typically higher vacuum level portions of the processing tools. Transferring substrates within the higher vacuum regions, which are typically at the backend of the processing tools, and through the link tools of the linked processing system will minimize the amount of or chance of contamination ending up on a substrate as it is passed between processing chambers in both processing tools during a substrate processing sequence. The link chambers have at least five facets. The system further includes two or more transfer vias. Each transfer via is coupled to a facet of the link chamber. The transfer vias are connectable to transfer modules of processing tools. The system further includes a link robot disposed in the link chamber operable to transfer one or more substrates between the transfer vias connectable to the transfer modules of the processing tools.

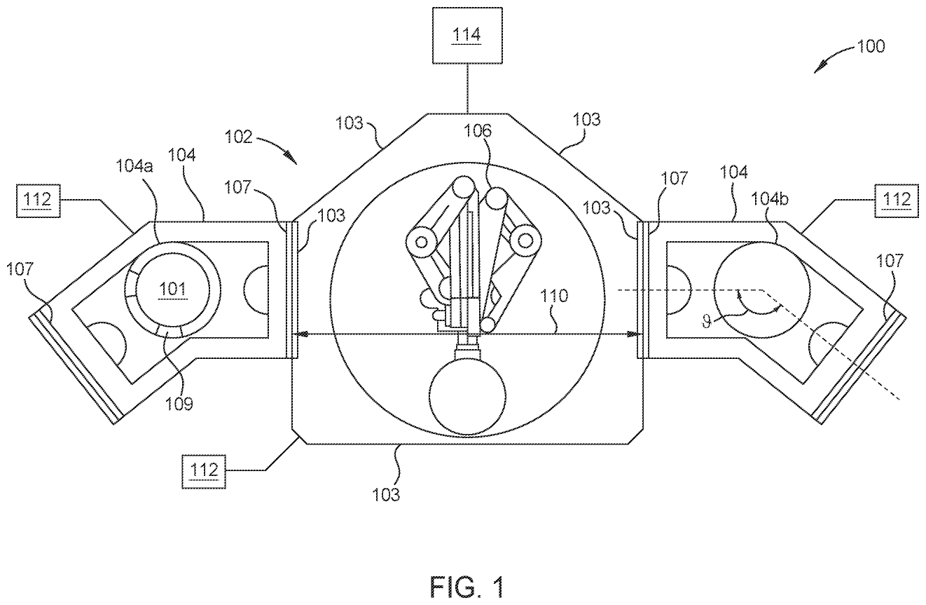

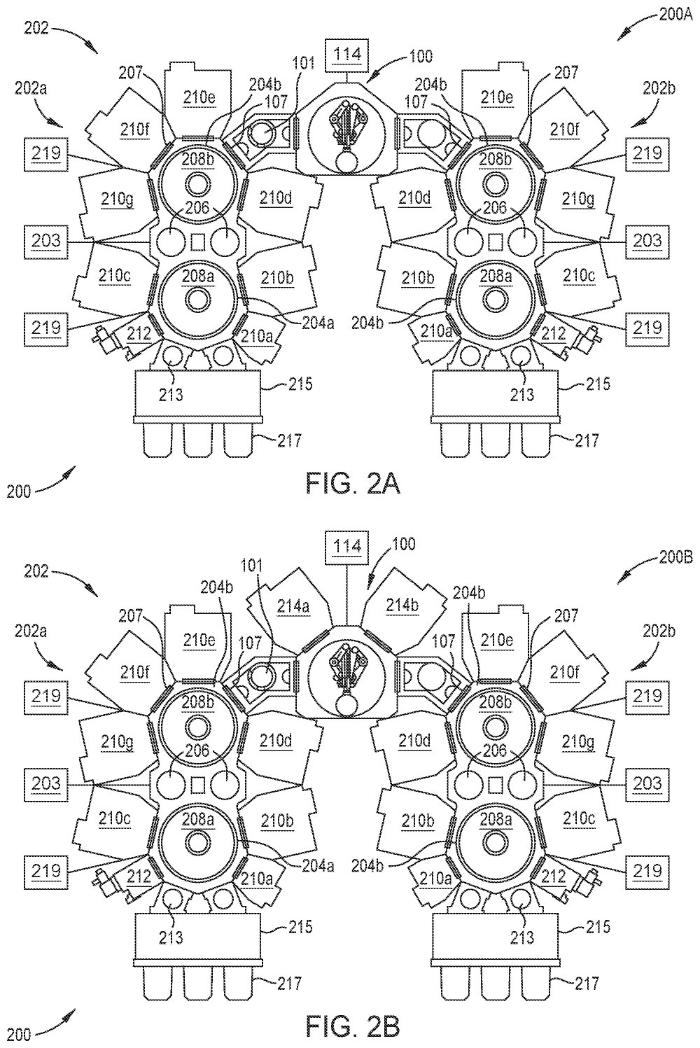

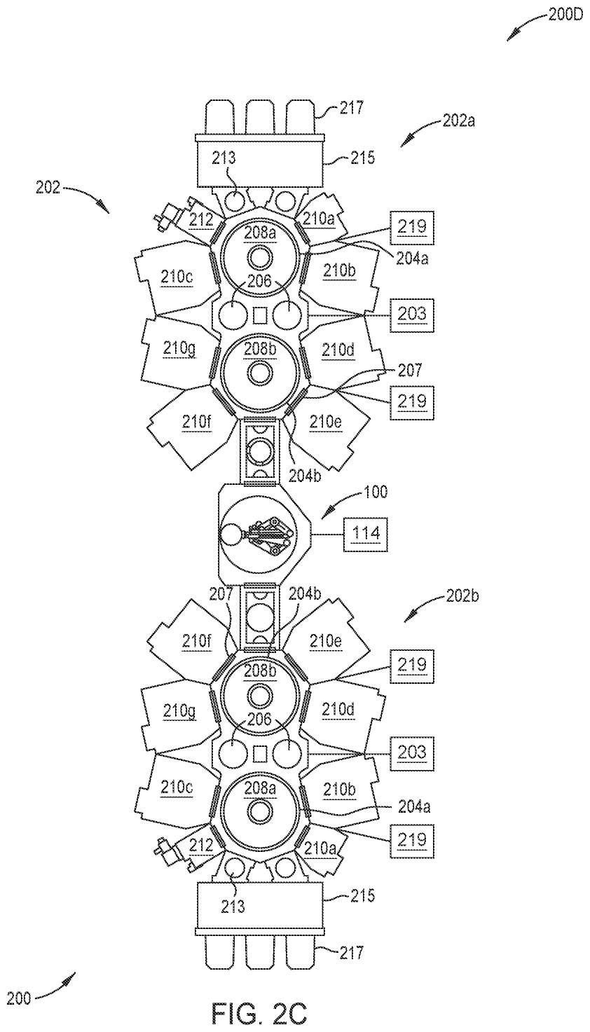

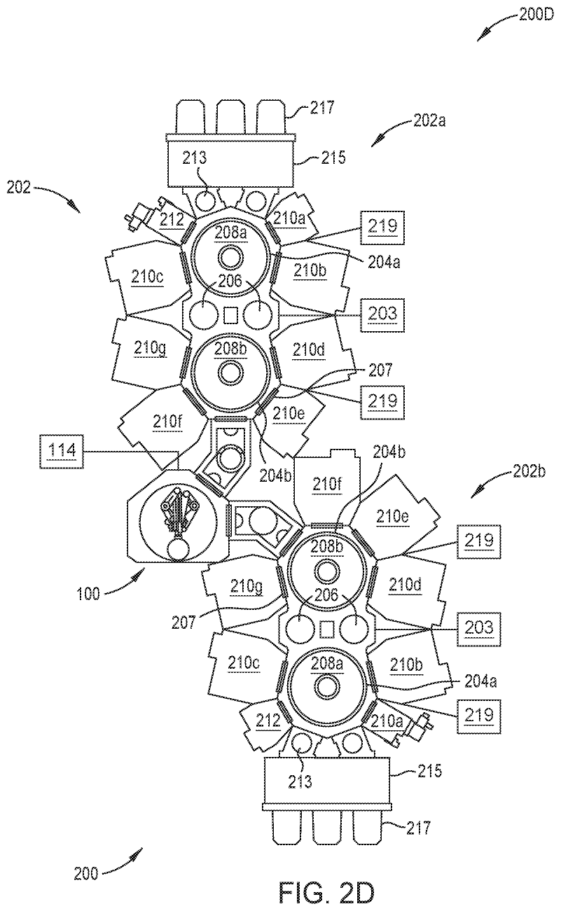

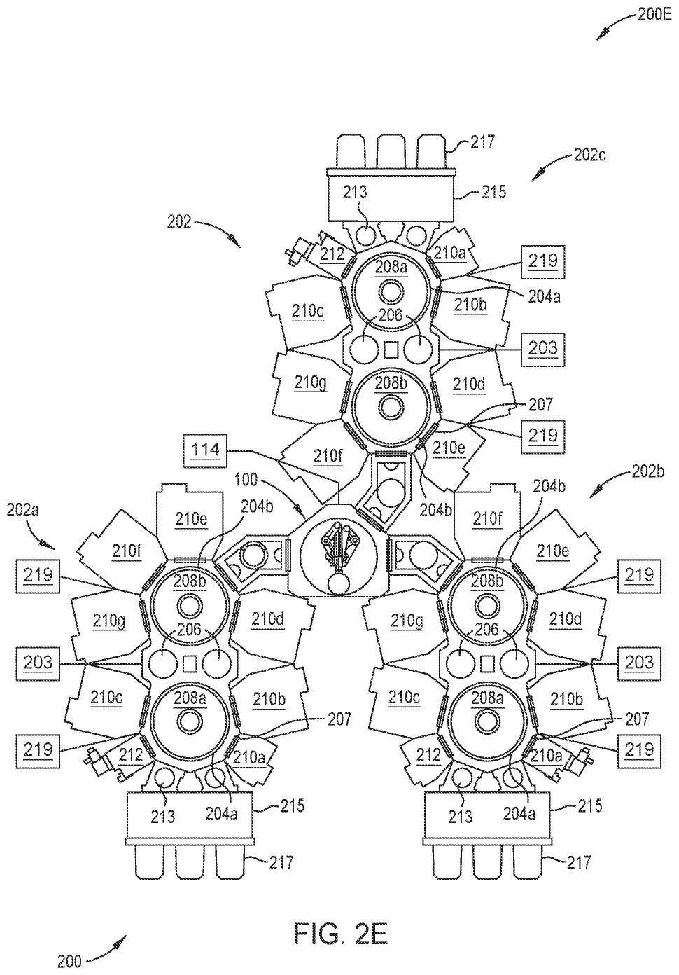

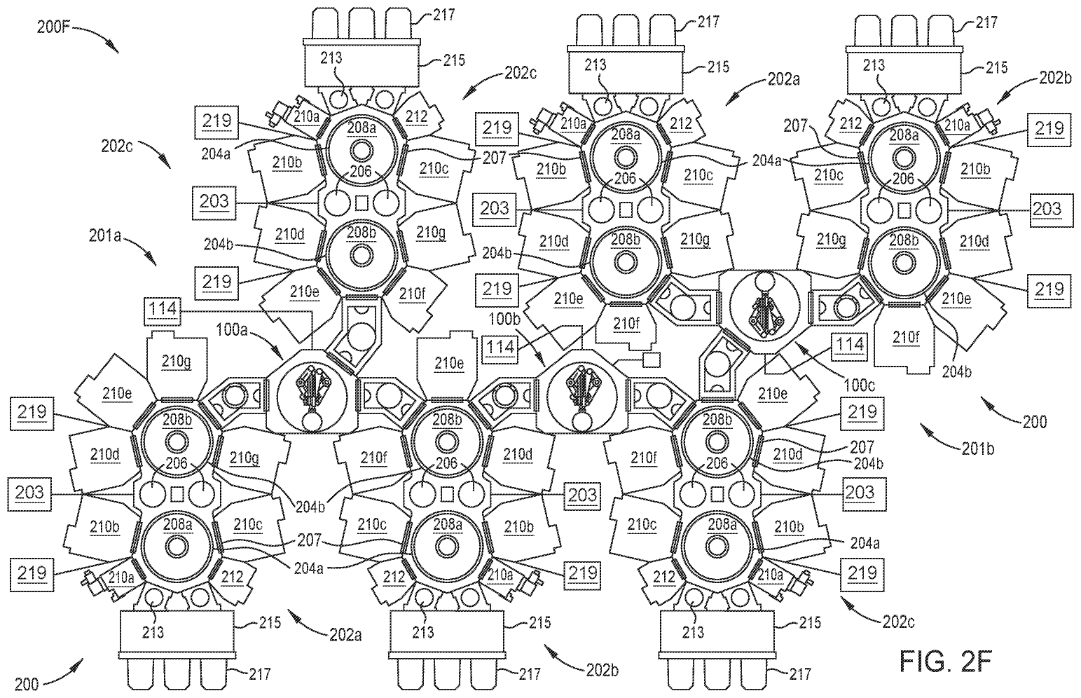

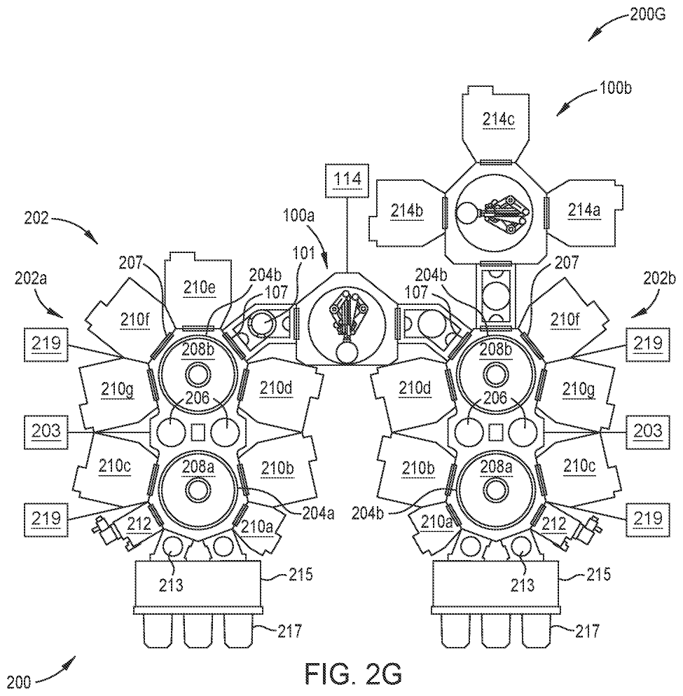

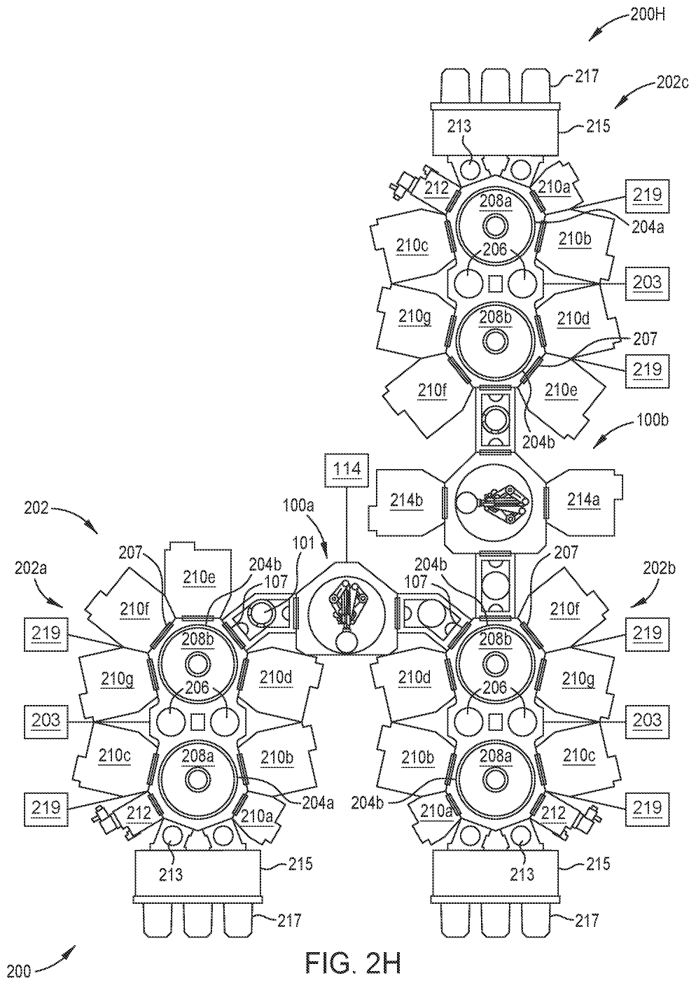

FIG. 1 is a schematic, top view of a link tool 100. The link tool 100 provides for arrangements 200A, 200B, 200C, 200D, 200E, 200F, 200G, and 200H of a linked processing system 200 shown in FIGS. 2A-2H. The link tool 100 includes a link chamber 102 with at least five facets 103. Each of the facets 103 are connectable to one of a transfer via 104 or an auxiliary chamber 214a, 214b (shown in FIGS. 2B and 2H), and 214c (shown in FIG. 2G). The link chamber 102 includes a link robot 106 disposed therein. In one embodiment, which can be combined with other embodiments described herein, the link robot 106 is operable to transfer one or more substrates 101 between second transfer modules 204b (shown in FIGS. 2A-2H) of processing tools 202 (shown in FIGS. 2A-2H). In another embodiment, which can be combined with other embodiments described herein, the link robot 106 is operable to transfer one or more substrates 101 from the transfer vias 104 connectable to the second transfer modules 204b (shown in FIGS. 2A-2H) of processing tools 202 (shown in FIGS. 2A-2H). In embodiments of the arrangements 200B and 200H, the link robot 106 is operable to transfer one or more substrates 101 to either of the auxiliary chambers 214a, 214b. In embodiments of the arrangement 200G, the link robot 106 is operable to transfer one or more substrates 101 to the auxiliary chambers 214a, 214b, or 214c. The link robot 106 includes an extension of about 36 inches to about 50 inches. In one embodiment, the extension is about 50 inches. The extension of the link robot 106 provides for the ability to transfer the substrates 101 between the second transfer modules 204b, the link chamber 102, and the auxiliary chambers 214a, 214b, 214c. The extension allows for a length 110 of the link chamber 102 to be about 105 inches to about 139 inches. In one embodiment, the length 110 is about 110 inches.

The link chamber 102 includes at least two transfer vias 104. Each transfer via 104 is coupled to a second transfer chamber 208b (as shown in FIGS. 2A-2H) such that the respective processing tool 202 is coupled to link chamber 102. Coupling adjacent processing tools 202 to the link chamber 102 at the second transfer modules 204b provides for the utilization of floor space away from the factory interfaces 215 of the processing tools 202. Furthermore, each of the transfer vias 104 may be angled at angle ϑ relative to the center of staging positions 104a, 104b of the transfer vias 104. In embodiments with angled transfer vias 104, each angle ϑ of each of the transfer vias 104 is the same. In one example, the angle ϑ is about 90 degrees to about 180 degrees. In another example, angle ϑ is about 30 degrees to about 50 degrees. Utilization of floor space away from the factory interfaces 215, and in some embodiments the same angle ϑ of each the transfer vias 104, minimizes the floor space required by the linked processing system 200 and allows for otherwise empty space on the manufacturing facility to be utilized. As shown in the arrangement 200B of the linked processing system 200, the coupling of adjacent processing tools 202 to the link chamber 102 at the second transfer modules 204b provides for space for the auxiliary chambers 214a, 214b. As shown in the arrangements 200E, 200F, and 200H of the linked processing system 200, the coupling of adjacent processing tools 202 to the link chamber 102 at the second transfer modules 204b provides for the coupling of a third processing tool 202c to the link chamber 102 such that the linked processing system 200 includes three processing tools 202.

At least one of the two or more transfer vias 104 includes a substrate alignment device 109 that is positioned at one or more of the staging positions 104a, 104b (e.g., left staging position 104a and/or right staging position 104b in FIG. 1). The substrate alignment device 109 is configured to orient a feature on a substrate 101 (i.e., wafer notch) in a correct orientation for processing in the process chambers of a first processing tool 202a, a second processing tool 202b, or a third processing tool 202c. In one embodiment, which can be combined with other embodiments described herein, the substrate alignment device 109 of the transfer vias 104 includes one or more of a notch finder, a substrate aligner, or re-orienter. The substrate alignment device 109 may determine and/or adjust the alignment and/or orientation of the substrate 101 as the substrate 101 passes between the first, second, and third processing tools 202a, 202b, 202c.

Valves 107 are disposed at the interfaces of transfer vias 104 and the link chamber 102, the interfaces of the auxiliary chambers 214a, 214b, 214c and the link chamber 102, and the interfaces of the second transfer modules 204b and the transfer vias 104. In one embodiment, which can be combined with other embodiments described herein, the valves are slit valves and/or gate valves. Thus, the link chamber 102 can be separately isolated from the transfer vias 104, the link chamber 102 can be separately isolated from the auxiliary chambers 214a, 214b, 214c and the transfer vias 104 can be separately isolated from the second transfer modules 204b of the processing tools 202. Vacuum pumps 112, such as cryopumps, turbopumps, or the like, may be coupled to the transfer vias 104 and link chamber 120. The vacuum pumps 112 are operable to maintain the vacuum level of one or more of the transfer vias 104 or the link chamber 120. The vacuum level may increase or decrease in each of the transfer vias 104 and the link chamber 120 as one or more substrates 101 are transferred between the second transfer modules 204b of the processing tools 202, the link chamber 102, and the auxiliary chambers 214a, 214b, 214c.

The link tool 100 includes a system controller 114 including a substrate handling system. The substrate handling system is a centralized server that implements predictive modeling, such as machine learning, artificial intelligence, and/or deep learning, to increase throughput of the linked processing system 200. The system controller 114 is configured to be in communication with tool controllers 203 of the processing tools 202. The system controller 114 is operable to receive data from the tool controllers 203, apply predictive modeling to the data, and provide instructions to the tool controllers 203 corresponding to process commands directed to processing in and transfer of one or more substrates from the process chambers of the processing tools 202.

FIGS. 2A-2H are schematic, top views of the arrangements 200A, 200B, 200C, 200D, 200E, 200F, 200G, and 200H of the linked processing system 200 according to embodiments described herein. The linked processing system 200 of the arrangements 200A-200D and 200G includes the first processing tool 202a connected to the second processing tool 202b via the link tool 100 as described herein. The linked processing system 200 of the arrangement 200E includes the first processing tool 202a, the second processing tool 202b, and a third processing tool 202c connected to each other via the link tool 100. The linked processing system 200 of the arrangement 200F includes a first cluster 201a and a second cluster 201b of the first processing tool 202a, the second processing tool 202b, and the third processing tool 202c. The first cluster 201a includes the first processing tool 202a, the second processing tool 202b, and the third processing tool 202c coupled to a first link tool 100a. The second cluster 201b includes the first processing tool 202a, the second processing tool 202b, and the third processing tool 202c coupled to a second link tool 100b. The first cluster 201a and the second cluster 201b are connected to each other by a third link tool 100c. The linked processing system 200 of the arrangement 200H includes the first processing tool 202a and the second processing tool 202b connected to each other via the first link tool 100a. The second processing tool 202b and the third processing tool 202c are connected to each other via the second link tool 100b.

In one or more embodiments of the linked processing system 200 disclosed herein, the processing tools 202 (e.g., first, second, and third processing tools 202a, 202b, 202c) may include the Endura 2 mainframe or an Endura 3 mainframe available from Applied Materials, Inc. of Santa Clara, Calif. Each processing tool 202 includes a first transfer module 204a, the second transfer module 204b, and pass-through modules 206 connecting a first transfer chamber 208a of the first transfer module 204a to the second transfer chamber 208b of the second transfer module 204b. The first transfer module 204a includes process chambers 210a, 210b, 210c (first, second, and third), an ancillary chamber 212, and load lock chambers 213. The second transfer module 204b includes process chambers 210d, 210e, 210f, 210g (fourth, fifth, sixth, and seventh). In the embodiments of the arrangement 200F, the second transfer module 204b of one processing tool 202 of the first cluster 201a and the second transfer module 204b of another processing tool 202 of the second cluster 201b include process chambers 210d, 210e, 210f.

Each of the first and second transfer modules 204a, 204b include a substrate handling robot (not shown) in the first and second transfer chambers 208a, 208b. The substrate handling robot of the first transfer module 204a is operable to transfer substrates between the load lock chambers 213, the first transfer chamber 208a, the process chambers 210a-210c, the ancillary chamber 212, and the pass-through modules 206. The substrate handling robot of the second transfer module 204b is operable to transfer substrates between the pass-through modules 206, the second transfer chamber 208b, the process chambers 210d-210g, and the transfer via 104. Each processing tool 202 includes load lock chambers 213 that are coupled to a factory interface 215. The factory interfaces 215 separately provides substrates 101 to a respective processing tool 202 via one or more factory interface (FI) robots (not shown) and front opening unified pods (FOUPs) 217.

Valves 207 are disposed at the interfaces of the process chambers 210a, 210b, 210c, the ancillary chamber 212, and the load lock chambers 213 and the first transfer chamber 208a of the first transfer module 204a. The valves 207 are also disposed at the interfaces of the process chambers 210d, 210e, 210f, 210g and the second transfer chamber 208b of the second transfer module 204b. In one embodiment, which can be combined with other embodiments described herein, the valves 207 are slit valves and/or gate valves. Thus, the process chambers 210a-210f can be separately isolated from the transfer vias 104, and the transfer vias 104 can be separately isolated from the first and second transfer chambers 208a, 208b. Vacuum pumps 219, such as cryopumps, turbopumps, or the like, may be coupled to the transfer vias 104 and the first and second transfer chambers 208a, 208b. Vacuum pumps 219 are operable to maintain the vacuum levels of the first and second transfer chambers 208a, 208b. The vacuum level may increase or decrease in each of the first and second transfer chambers 208a, 208b as one or more substrates 101 are transferred between the first transfer chamber 208a and the second transfer chamber 208b. Furthermore, the vacuum level may increase or decrease as one or more substrates 101 are transferred between the second transfer chamber 208b and the link tool 100.

In this configuration, the transfer of the substrates 101 between the first processing tool 202a and the second processing tool 202b (and the third processing tool 202c in embodiments of the arrangements 200E, 200F, 200H) can be completed while the substrates 101 are disposed within a high vacuum environment (e.g., 10⁻⁷-10⁻⁹ Torr), since the vacuum level in the second transfer chambers 208b are maintained at a higher base pressure than the vacuum level maintained in the first transfer chambers 208a. Typically, the base pressure or vacuum level increases (i.e., lower pressure) as the substrate 101 is moved through the first transfer module 204a to the second transfer module 204b within a processing tool 200 in a direction from the load lock chambers 213 (e.g., 10⁻³ Torr) to the second transfer chamber 208b (e.g., 10⁻⁷-10⁻⁸ Torr) and the process chambers 210d-210g (e.g., 10⁻⁸-10⁻⁹ Torr). It is believed that transferring substrates within the high vacuum regions of both processing tools, such as the first processing tool 202a and the second processing tool 202b, and through the link tool 100 will minimize the amount of or chance of contamination from ending up on a substrate as it is passed between processing chambers in both processing tools during a substrate processing sequence.

The process chambers 210a-210f and the auxiliary chambers 214a, 214b, 214c may be any type of process chambers such as deposition chambers (e.g., physical vapor deposition (PVD) chambers, chemical vapor deposition (CVD) chambers, plasma enhanced chemical vapor deposition (PECVD) chambers, atomic layer deposition (ALD) chambers, plasma enhanced atomic layer deposition (PEALD), etch chambers, degas chambers, and/or any other type of process chambers. The types of the process chambers 210a-210f and the auxiliary chambers 214a, 214b, 214c in the arrangements 200A, 200B, 200C, 200D, 200E, 200F, 200G, and 200H of the linked processing system 200 are interchangeable in the processing tools 202. The process chambers 210a-210f of the first processing tool 202a, the second processing tool 202b, and the third processing tool 202c include any combination of PVD chambers, CVD chambers, PECVD chambers, ALD chambers, PEALD chambers, etch chambers, degas chambers, or any other type of process chambers. The combination of process chambers may be different or the same in each of the first processing tool 202a, the second processing tool 202b, and the third processing tool 202c.

In operation, the process chambers 210a-210f of the first processing tool 202a, the second processing tool 202b, and the third processing tool 202c are interchangeable. For example, a method for depositing a contact structure in a semiconductor device in each of the first processing tool 202a, the second processing tool 202b, and the third processing tool 202c may include a combination of PVD, CVD, and ALD chambers. In the method, a barrier layer, a wetting layer, and metal layer may be deposited. Each of the barrier layer, wetting layer, and metal layer may be deposited by one or more of a PVD, a CVD, a PECVD, an ALD, or a PEALD process. In one example, if the process chamber 210a (configured as a CVD chamber to deposit a barrier layer) of the first processing tool 202a is inoperable, undergoing repair, or undergoing replacement, the substrate 101 may be transferred to one of the process chambers 210a-210f of the second processing tool 202b and/or the third processing tool 202c configured as the CVD chamber to deposit the barrier layer. The process chamber 210e of the first processing tool 202a of the arrangements 200G and 200H may be replaced with a transfer via 104 of a link tool 100. Therefore, the arrangements 200G may include a third link tool 100 with the auxiliary chambers 214a, 214b, or 214c and the arrangements 200H may include a third link tool 100 with the auxiliary chambers 214a, 214b and a fourth processing tool.

The substrate handling system of the system controller 112 in communication with the tool controllers 203 of the processing tools 202 receives data corresponding to the throughput of each of the process chambers 210a-210f. The system controller 112 is operable to apply predictive modeling to the data in order to provide instructions to the tool controllers 203 corresponding to process commands directed to processing in and transfer of one or more substrates 101 from the process chambers 210a-210f of the processing tools 202. The system controller 112 may also provide an output corresponding to the optimal combination of PVD chambers, CVD chambers, PECVD chambers, ALD chambers, PEALD chambers, etch chambers, degas chambers, or any other type of process chambers for the process chambers 210a-210f of the first processing tool 202a, the second processing tool 202b, and the third processing tool 202c and the auxiliary chambers 214a, 214b of the link tool 100.

In summation, link tools and linked processing systems having two or more processing tools connected by one or more link tools are described herein. Each arrangement of the link processing system includes adjacent processing tools coupled to a link chamber at the transfer modules at the backend of the processing tools. To minimize the amount of or chance of contamination from ending up on a substrate as it is passed between processing chambers in both processing tools during a substrate processing sequence, substrates are transferred within the high vacuum regions at the backend of the processing tools and through the link tools of the linked processing system. Additionally, the positioning of the link tool(s) at the backend utilizes floor space away from the factory interfaces of the processing tools, which can be important in some semiconductor fab processing system layouts. Utilization of floor space away from the factory interfaces, and in some embodiments the same angle of each the transfer vias of the linked tool, minimizes the floor space required by the linked processing system and allows for otherwise empty space on the manufacturing facility to be utilized.

While the foregoing is directed to examples of the present disclosure, other and further examples of the disclosure may be devised without departing from the basic scope thereof, and the scope thereof is determined by the claims that follow.

What is claimed is:

1. A system, comprising:
a link chamber having at least five facets;
two or more transfer vias, each transfer via coupled to a facet of the link chamber, the transfer vias connectable to transfer modules of processing tools; and
a link robot disposed in the link chamber operable to transfer one or more substrates from the transfer vias connectable to the transfer modules of the processing tools.

2. The system of claim 1, wherein valves are disposed at interfaces of the transfer vias and the link chamber, and the valves are disposable at the interfaces of the transfer modules and the transfer vias.

3. The system of claim 2, wherein vacuum pumps are coupled to the transfer vias and the link chamber.

4. The system of claim 3, wherein the vacuum pumps are cryopumps or turbopumps.

5. The system of claim 2, wherein the valves are slit valves or gate valves.

6. The system of claim 1, further comprising two auxiliary chambers.

7. The system of claim 6, wherein each auxiliary is one of a deposition chamber, an etch chamber, or a degas chamber.

8. The system of claim 1, further comprising a system controller in communication with tool controllers of the processing tools, the system operable to receive data from the tool controllers of the processing tools, apply predictive modeling to the data, and provide instructions to the tool controllers corresponding to process commands directed to processing in and transfer of one or more substrates from process chambers of the processing tools.

9. A system, comprising:
a link tool, the link tool having:
a link chamber having at least five facets;
a first transfer via coupled to a first facet of the link chamber and a second transfer via coupled to a second facet of the link chamber; and
a link robot disposed in the link chamber; and
a first processing tool coupled to the first transfer via and a second processing tool coupled to the second transfer via, each of the first processing tool and the second processing tool having:
a first transfer module, the first transfer module comprising:
load lock chambers coupled between a factory interface and a first transfer chamber of the first transfer module;
an ancillary chamber and first, second, and third process chambers coupled to the first transfer chamber;
a second transfer module, the second transfer module comprising:
pass-through chambers connecting the first transfer module and the second transfer module; and
fourth, fifth, sixth, and seventh process chambers coupled to a second transfer chamber, the second transfer chamber coupled to one of the first transfer via or the second transfer via.

10. The system of claim 9, wherein valves are disposed at interfaces of:
the first transfer via and the link chamber, and the second transfer via and the link chamber;
the second transfer chamber of the first processing tool and the first transfer via, and the second transfer chamber of the second processing tool and the second transfer via;
the ancillary chamber and the first, second, and third process chambers and the first transfer chamber; and
the fourth, fifth, sixth, and seventh process chambers and the second transfer chamber.

11. The system of claim 10, wherein vacuum pumps are coupled to the first transfer vias, the second transfer via, the link chamber, the first transfer module, and the second transfer module.

12. The system of claim 9, wherein each of the first transfer via and the second transfer via includes a staging position, the staging position of at least one of the first transfer via and the second transfer via having a substrate alignment device.

13. The system of claim 12, wherein each of the first transfer via and the second transfer via are angled relative to a center of the staging position at the same angle.

14. The system of claim 9, further comprising two auxiliary chambers, each of the two auxiliary chambers coupled to a third facet and a fourth facet of the link chamber.

15. The system of claim 9, wherein the first, second, third, fourth, fifth, sixth, and seventh process chambers correspond to one of a deposition chamber, an etch chamber, or a degas chamber.

16. The system of claim 9, wherein the link tool includes a system controller in communication with tool controllers of the first processing tool and the second processing tool, the system controller operable to receive data from tool controllers, apply predictive modeling to the data, and provide instructions to the tool controllers corresponding to process commands directed to processing in and transfer of one or more substrates from process chambers of the first processing tool and the second processing tool.

17. A system, comprising:
a first link tool, the first link tool having:
a link chamber having at least five facets;
a first transfer via coupled to a first facet of the link chamber, a second transfer via coupled to a second facet of the link chamber, and a third transfer via coupled to a third facet of the link chamber; and
a link robot disposed in the link chamber; and
a first processing tool coupled to the first transfer via, a second processing tool coupled to the second transfer via, and a third processing tool coupled to the third transfer via, each of the first processing tool, the second processing tool, and the third processing tool having:
a first transfer module, the first transfer module comprising:
load lock chambers coupled between a factory interface and a first transfer chamber of the first transfer module;
an ancillary chamber and first, second, and third process chambers coupled to the first transfer chamber;
a second transfer module, the second transfer module comprising:
pass-through chambers connecting the first transfer module and the second transfer module; and
at least fourth, fifth, and sixth process chambers coupled to a second transfer chamber, the second transfer chamber coupled one of the first transfer via, the second transfer via, or the third transfer via.

18. The system of claim 17, wherein each of the first transfer via, the second transfer via, and the third transfer via include a staging position, the staging position of at least one of the first transfer via, the second transfer via, and the third transfer via having a substrate alignment device.

19. The system of claim 18, wherein each of the first transfer via, the second transfer via, and the third transfer via are angled relative to a center of the staging position at the same angle.

20. The system of claim 17, further comprising:
a second link tool, the first transfer via of the second link tool coupled to the second transfer chamber of the third processing tool and the second transfer via of the second link tool coupled to a fourth processing tool; and
a third link tool, the first transfer via of the third link tool coupled to the second transfer chamber of the fourth processing tool, the second transfer via of the third link tool coupled to a fifth processing tool, and the third transfer via of the third link tool coupled to a sixth processing tool.
